(19) United States
(12) Patent Application Publication
(10) Pub. No.: US 2025/0245392 A1
(43) Pub. Date: Jul. 31, 2025

(54) ESTIMATING OBSTACLE MATERIALS FROM FLOOR PLANS

(71) Applicant: Telefonaktiebolaget LM Ericsson (publ), Stockholm (SE)

(72) Inventors: Taesuh PARK, Santa Clara, CA (US); Jianfu ZHANG, Santa Clara, CA (US); Hun CHANG, Santa Clara, CA (US)

(73) Assignee: Telefonaktiebolaget LM Ericsson (publ), Stockholm (SE)

(21) Appl. No.: 18/845,868

(22) PCT Filed: May 13, 2022
(86) PCT No.: PCT/IB2022/054451

§ 371 Date: Sep. 10, 2024

Related U.S. Application Data
(60) Provisional application No. 63/319,246, filed on Mar. 11, 2022.

(51) Int. Cl. G06F 30/13; G06F 30/27

(52) U.S. Cl. CPC G06F 30/13; G06F 30/27

(57) ABSTRACT

Estimating materials of obstacles from a floor plan (310) is described. A floor plan is loaded (210) and preprocessed (215, 410). A material map (510) for the preprocessed floor plan is generated using a machine learning model for estimating materials of obstacles of the floor plan (220, 225). An obstacle map (610) is generated from the preprocessed floor plan that includes segmented obstacles as line segments. An augmented floor plan (710) is generated (225) based on a combination of the generated material map and the generated obstacle map, where the augmented floor plan identifies the estimated material of the segmented obstacles.

### CROSS-REFERENCE TO RELATED APPLICATIONS

This application claims the benefit of U.S. Provisional Application No. 63/319,246, filed Mar. 11, 2022, which is hereby incorporated by reference.

### TECHNICAL FIELD

Embodiments of the invention relate to the field of cellular network design; and more specifically, to estimating obstacle materials from floor plans.

### BACKGROUND ART

A cellular network design for indoor users is relatively challenging compared to outdoor cellular network designs because there are many indoor obstacles which block or distort radio signal propagations. While outdoor cellular network designs usually require only one radio station to cover an area of hundreds meter in radius, indoor designs require multiple radio transmitters to cover all corners inside a floor. For determining the positions of radio transmitters, the indoor design conventionally considers layout and material of walls, columns, and other fixtures.

There currently exist certain challenge(s). Radio Frequency (RF) engineers may use a dedicated radio ray tracing simulation tool to predict the radio propagation pattern caused by a new radio transmitter installation through walls and columns of various materials. Material is a primary factor of determining radio signal attenuation. For example, drywall allows radio signal to penetrate with decreased strength while metal or heavy concrete columns reflect radio signals. The accuracy of network performance predictions is highly dependent on the accuracy of this building model so the designer must take great care to ensure that obstacles such as walls, columns, and other fixtures are accurately represented in the building model. Contrary to the wall layout information that is easily acquired via a floor plan file, material information of obstacles (e.g., walls, columns, fixtures, etc.) usually require onsite investigation because almost all floor plans available in the market do not provide such detailed information. For the onsite investigation, a field technician visits a building to identify materials of its obstacles, and then radio designers augment the floor plan based on the material information to prepare for reliable RF simulation. However, due to the nature of the augmentation which is dependent on rough and inconsistent reports from the field technicians and time-consuming obstacle segmentation in a floor plan by eyeballing, that task has been a bottleneck of the indoor radio design process.

### SUMMARY OF THE INVENTION

Estimating obstacle materials from floor plans is described. In one aspect a method is performed for estimating materials of obstacles from a floor plan, the method including loading and preprocessing the floor plan; generating a material map for the preprocessed floor plan using a machine learning model for estimating materials of obstacles of the floor plan; generating an obstacle map from the preprocessed floor plan that includes segmented obstacles as line segments; and generating, based on a combination of the generated material map and the generated obstacle map, an augmented floor plan that identifies the estimated material of the segmented obstacles. The method may further include providing the generated augmented floor plan to a radio frequency (RF) design/simulation tool. Providing the generated augmented floor plan to the RF design/simulation tool may include converting the generated augmented floor plan to a format readable by the RF design/simulation tool. The preprocessing of the floor plan may include setting one or more regions of interest. The preprocessing of the floor plan may include removing noise and unrelated peripheral texts and lines. The machine learning model may be a U-Net model that is pretrained as a generator in a conditional generative adversarial network (cGAN). The cGAN may use a function that considers losses on obstacles only when training the machine learning model such as a focal Tversky loss function. The discriminator of the cGAN may be a convolutional PatchGAN classifier. The obstacles of the floor plan may include one or more walls, one or more columns, and/or one or more fixtures. Generating the obstacle map may include vectorizing the preprocessed floor plan to the line segments. The floor plan may be a raster graphics image, and the generated obstacle map may be a vector graphic. The generated material map and the generated obstacle map may be spatially aligned.

In further aspects, one or more embodiments of a non-transitory computer-readable medium or distributed media containing computer-executable program instructions or code portions stored thereon are disclosed for performing one or more embodiments of the methods of the present invention when executed by a processor entity of an apparatus, an electronic device, or other computing device. Further features of the various embodiments are as claimed in the dependent claims.

### BRIEF DESCRIPTION OF THE DRAWINGS

The invention may best be understood by referring to the following description and accompanying drawings that are used to illustrate embodiments of the invention. In the drawings:

FIG. 1 is a block diagram of the proposed system for estimating obstacle materials from floor plans according to an embodiment.

FIG. 2 is a flow diagram that illustrates exemplary operations for estimating obstacle materials from floor plans according to an embodiment.

FIG. 3 shows an exemplary floor plan according to an embodiment.

FIG. 4 shows an exemplary preprocessed floor plan of the floor plan shown in FIG. 3 according to an embodiment.

FIG. 5 shows an example material map generated for the preprocessed floor plan of FIG. 4 according to an embodiment.

FIG. 6 shows an exemplary obstacle map according to an embodiment.

FIG. 7 shows an exemplary augmented floor plan according to an embodiment.

FIG. 8 shows an exemplary DNN model for estimating obstacle materials from floor plans according to an embodiment.

FIG. 9 illustrates an electronic device according to an embodiment.

### DETAILED DESCRIPTION

An embodiment for estimating obstacle materials from floor plans is described. There currently exist certain challenge(s) with existing cellular network designs. An embodiment described herein includes a machine-learning-based solution of estimating materials of the obstacles for a given floor plan. By training a machine learning model (e.g., deep neural network (DNN) model) using the previously augmented floor plans, the solution automates the augmentation of floor plans with material information. The machine learning model predicts material properties of obstacles within a floor plan and/or blueprint.

The way of training a model (e.g., a DNN model) for estimating materials from graphical thin line segments is different from other generative adversarial network (GAN) solutions. For instance, most pixel-to-pixel GANs have problems in treating such high-frequency graphical images as both input and output.

Certain embodiments may provide one or more of the following technical advantage(s). The solution reduces lead time from several days to several hours for augmenting floor plans to include obstacle material information and thereby enhances the productivity and efficiency of tools for indoor radio design. Reduced lead time and cost of field investigation allows better scaling for indoor radio design.

Some of the embodiments contemplated herein will now be described more fully with reference to the accompanying drawings. Embodiments are provided by way of example to convey the scope of the subject matter to those skilled in the art.

In an exemplary implementation, the system trains a model such as a deep neural network (DNN) to estimate materials of obstacles such as walls, columns, and/or fixtures, in a floor plan and/or blueprint. The DNN may be trained using conditional GAN (cGAN) to estimate the material of obstacles. A pixel-to-pixel network can be trained using pairs of floor plans that do not include obstacle material information and their corresponding material-augmented floor plans that have been made by human designers.

The original floor plan and/or blueprint may be provided as a Portable Document Format (PDF) file. The floor plan may be extracted from the input file and stored in a raster graphic format (e.g., Portable Network Graphic (PNG)). The extracted floor plan may be a monochrome or grayscale image without noise.

In an embodiment, region(s) of interest are set for the floor plan to reduce unwanted padding and auxiliary texts. The region(s) of interest may be performed automatically and/or refined by a user. This helps suppress unnecessary artifacts of the model. For example, one or more polygons may be drawn to determine the one or more regions of interest. In an embodiment, noise reduction may be used to identify and remove noise (e.g., dirty dots, irrelevant grid lines, company logos, peripheral texts, etc.). The maximum size of the input image may be limited by the size of available memory: for example, 512×512 pixels.

A material map for the input floor plan is generated using the machine learning model. The material map may be generated from a preprocessed version of the input floor plan. The material map is used for estimating materials of obstacles found in the input floor plan. The material map may be in a raster graphic format. The indication can be made in different ways. In one way, color may be used to identify different materials. For instance, pink may identify drywall; sky blue may identify glass; brown may identify heavy concrete; dark blue may identify metal; and yellow may identify partition. Of course, these are examples and different colors may identify different materials. In addition to and/or in lieu of colors, different line styles may be used to identify different materials (e.g., solid line, dotted line, dashed line, dot-dash lines, etc.).

An obstacle map is generated for the input floor plan that includes segmented obstacles. The obstacle map may be generated from a preprocessed version of the input floor plan. For instance, the obstacle map may be generated through a raster to vector conversion of the raster graphic input floor plan or preprocessed floor plan and segmenting the lines. Thus, the obstacle map is a vectorized version of the floor plan (e.g., a vectorized version of the preprocessed version of the input floor plan or a vectorized version of the input floor plan itself). Each line may be part of a different obstacle. The obstacle map does not identify the materials of the obstacles. The obstacle map may be generated automatically and/or be refined by a user (e.g., selecting and removing certain objects that are not relevant to the floor plan).

The material map and the obstacle map are spatially aligned. The overlap between the material map and the segmented obstacles is used to associate an obstacle segment to its material. For instance, metadata associated to a material “drywall” can be assigned to a line segment in the obstacle map that is spatially aligned with the material map. An augmented floor plan with obstacle material information that is readable by RF design/simulation tools is generated based on the combination of the generated material map and the segmented obstacles. The augmented floor plan may be a vector based graphic or equivalent that is readable by an RF simulation tool. RF engineers may use the design/simulation tool (e.g., a radio ray tracing simulation tool) to predict the radio propagation pattern caused by a new radio transmitter installation through obstacles such as walls and columns in the identified materials. For instance, the engineers may use the tool to virtually place radio transmitters on a floor, run the simulator that accounts for the identified obstacles and their respective materials, and evaluate the signal strength of the room and adjust as needed.

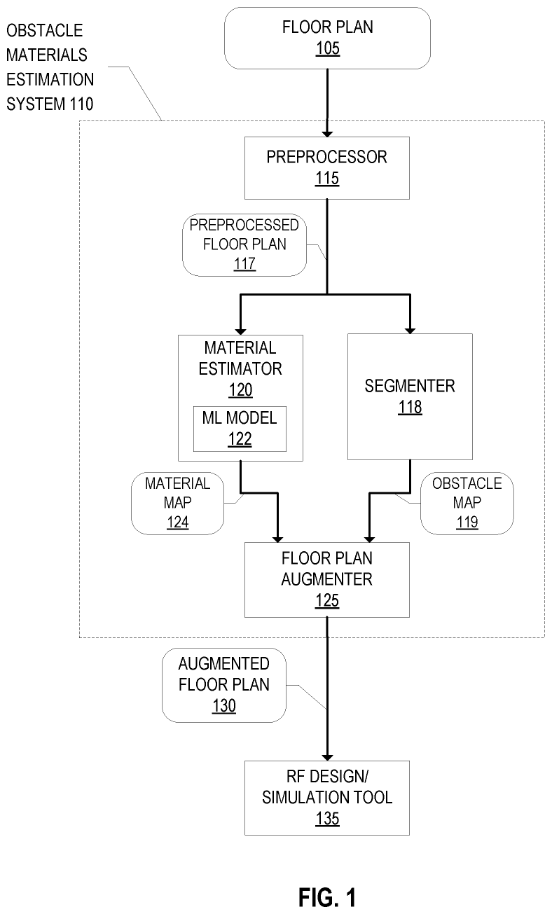

FIG. 1 is a block diagram of the proposed system for estimating obstacle materials from floor plans according to an embodiment. A floor plan 105 is provided as input to the obstacle materials estimation system 110. The floor plan 105 includes information about the floor layout of obstacles (e.g., walls, columns, fixtures, etc.). The floor plan 105 may be in a digital format such as PDF, JPG, PNG, etc. By way of example, the floor plan 105 may be a scanned representation of a physical floor plan.

The preprocessor 115 processes the input floor plan 105 and generates a preprocessed floor plan 117. Preprocessing includes preparing the data of the input floor plan 105 to make it suitable for the machine learning model. Preprocessing may include performing one or more of the following: removing color from the input floor plan (e.g., converting the image to grayscale), enhancing line quality (e.g., applying an extended difference-of-Gaussians algorithm), adding pads to crop the image, cropping the image, and normalizing the input floor plan. Cropping may include registering region(s) of interest. The registration of region(s) of interest may be performed automatically and/or refined by a user. Preprocessing may include the preprocessor 115 performing noise reduction to identify and remove noise (e.g., dirty dots, irrelevant grid lines, company logos, peripheral texts, etc.).

Preprocessing may include converting/partitioning the floor plan 105 accordingly to one or more sections that is fit to the machine learning model in the material estimator 120. For example, the floor plan may be too large for a single machine learning model due to computing hardware limitations. For instance, the maximum size and resolution of the input image may be limited by the size of available memory; for example, 512×512 pixels. If a large floor plan is scaled down to a smaller-sized floor plan of 512×512 pixels, regardless of its original dimension, many details such as obstacles can be lost and therefore the quality of the estimation of object materials is degraded. In an embodiment, the optimal size and dimension of each section is determined by the machine learning model and training data set. For example, 2,000 square feet may be set as the size of each section empirically. If the floor plan is too large for a single machine learning model, that floor plan is partitioned into several pieces and each piece is processed by the machine learning model one by one.

The segmenter 118 generates an obstacle map 119 from the preprocessed floor plan 117. For instance, the segmenter 118 may perform a raster to vector conversion of the raster graphic preprocessed floor plan 117 and segments the lines. The output obstacle map 119 may be provided to the floor plan augmenter 125.

As previously described, there are cases where the floor plan may be partitioned into multiple pieces to fit the machine learning model in in the material estimator 120. However, the segmenter 118 may be configured to process the same preprocessed floor plan but without the partitions. Thus, the material estimator 120 may receive a preprocessed floor plan that is partitioned into multiple sections and the segmenter 118 may receive the same preprocessed floor plan but without any partitions.

The material estimator 120 estimates materials represented in the preprocessed floor plan 117 using a machine learning model 122 and generates the material map 124. The material map 124 indicates the estimated materials, which may correspond to obstacles represented in the preprocessed floor plan 117. The indication can be made in different ways. In one way, color may be used to identify different materials. For instance, pink may identify drywall; sky blue may identify glass; brown may identify heavy concrete; dark blue may identify metal; and yellow may identify partition. Of course, these are examples and different colors may identify different materials. In addition to and/or in lieu of colors, different line styles may be used to identify different materials (e.g., solid line, dotted line, dashed line, dot-dash lines, etc.).

In an embodiment, the machine learning model 122 performs pixel-to-pixel estimation. For instance, the machine learning model 122 may be U-Net model that is pretrained as a generator in a cGAN and the discriminator uses a convolutional PatchGAN classifier. The machine learning model 122 has been trained using previous pairs of floor plans and their respective material maps before being used. In an embodiment, the machine learning model 122 is integrated within the material estimator 120.

When training the generator, in an embodiment a typical GAN loss function such as root mean square error (RMSE) is not used. Instead, a function that considers losses on obstacles only when training machine learning model such as a focal Tversky loss function is used when training the generator. The focal Tversky loss function suppresses the effect of a blank background in addition to the typical GAN loss. For each defined material (e.g., for each different color), a focal Tversky score is calculated by regarding other pixels (including blank) as background. Alpha value is a key parameter in focal Tversky loss. By choosing alpha values closer to 1 for each defined material (e.g., each color), additional level of control over the loss function yields the automatic suppression of blank pixels. By way of example, an alpha value may be set for the following colors: {“pink”: 0.99, “brown”: 0.9999, “light blue”: 0.9999, “yellow”: 0.9999, “yellow green”: 0.9999, “blue”: 0.9999, “orange”: 0.9999, “red”: 0.9999}.

In an embodiment, a single machine learning model 122 can be used for estimating the materials of objects for different kinds of structures (e.g., commercial buildings, residential buildings, industrial buildings). In another embodiment, different machine learning models are used for different structures (e.g., a first machine learning model specific for commercial buildings, a second machine learning model specific for residential buildings, and a third machine learning model specific for industrial buildings).

If there are multiple preprocessed floor plans due to the floor plan being partitioned into multiple pieces, the material estimator 120 processes each piece one by one. The material estimator 120 aggregates the multiple pieces (each one a material map) to reconstruct a larger material map corresponding with the floor plan 105.

The material map 124 and the obstacle map 119 are spatially aligned. The floor plan augmenter 125 combines the material map 124 (e.g., in a raster graphic format) and the obstacle map 119 (e.g., in a vector graphic format, usually) to generate the augmented floor plan 130. The overlap is used to associate an obstacle segment to its material. Although a vectorized obstacle map may be used for generating an augmented floor plan 130 for use in the RF design/simulation tool 135, it is also possible to use a raster graphical obstacle map for combining with the material map and then vectorize the combined map to make it readable by the RF design/simulation tool 135.

Although an embodiment is described where the segmenter 118 generates an obstacle map from the preprocessed floor plan, in another embodiment the segmenter 118 generates the obstacle map from the input floor plan 105 itself. In such an embodiment, the material map may not be spatially aligned with the obstacle map, and the floor plan augmenter 125 considers any spatial difference between the material map and the obstacle map when generating the augmented floor plan.

Various features of embodiments described herein can be performed by different electronic devices. The training of the machine learning model 122 may be performed on a server computing device that can be remote from the device(s) in which the obstacle materials estimation system 110 is executed. The obstacle materials estimation system 110 may be implemented in an electronic device such as a client computing device (e.g., a laptop, a desktop, a tablet, a mobile phone, a smartphone, etc.), a server computing device (which may include one or more physical or virtual computing elements), or distributed between the client computing device and a server computing device. As a first example, in an embodiment the pre-trained machine learning model 122 may be downloaded locally to a client computing device and that client computing device executes the obstacle materials estimation system 110 and may also locally execute the RF design simulation tool. As a second example, in an embodiment a user may use a client computing device to transmit (e.g., upload) the input floor plan 105 to a server computing device which then executes the obstacle materials estimation system 110. In the second example, in an embodiment the RF design/simulation tool 135 executes on the client computing device in which case the server computing device transmits the augmented floor plan 130 to the client computing device for integration and execution of the RF design/simulation tool. In the second example, in an embodiment the RF design/simulation tool 135 executes on the server computing device (with possible input from the client computing device), in which case the result (the output of the RF design/simulation tool) can be transmitted to the client computing device. In an embodiment, one or more of the individual components (e.g., the preprocessor 115, the material estimator 120, the segmenter 118, the floor plan augmenter 125, and the RF design/simulation tool 135) are executed in a client computing device and other one or more of those individual components are executed in a server computing device.

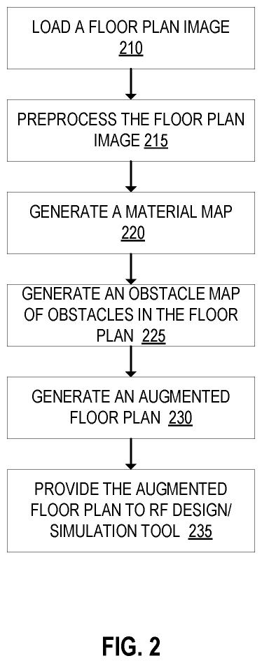

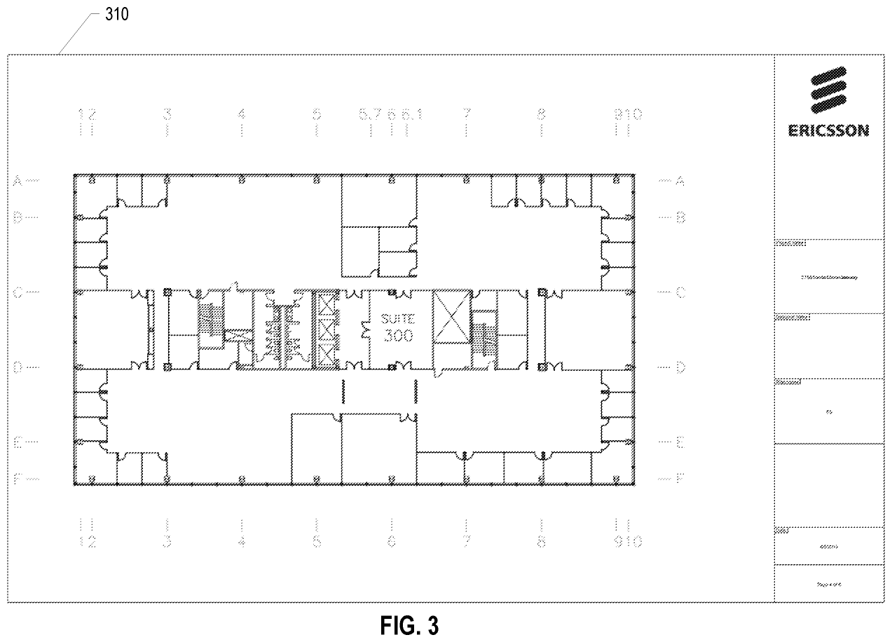

FIG. 2 is a flow diagram that illustrates exemplary operations for estimating obstacle materials from floor plans according to an embodiment. The operations of FIG. 2 are described with respect to the exemplary embodiment of FIG. 1. However, the operations of FIG. 2 can be performed by embodiments different from that of FIG. 1, and the embodiment of FIG. 1 can perform operations different from that of FIG. 2. The operations of FIG. 2 are also described with respect to FIGS. 3-7.

At operation 210, a floor plan image is loaded by the obstacle materials estimation system 110. The floor plan image (e.g., a PNG file) may be extracted from a PDF file. FIG. 3 shows an exemplary floor plan 310.

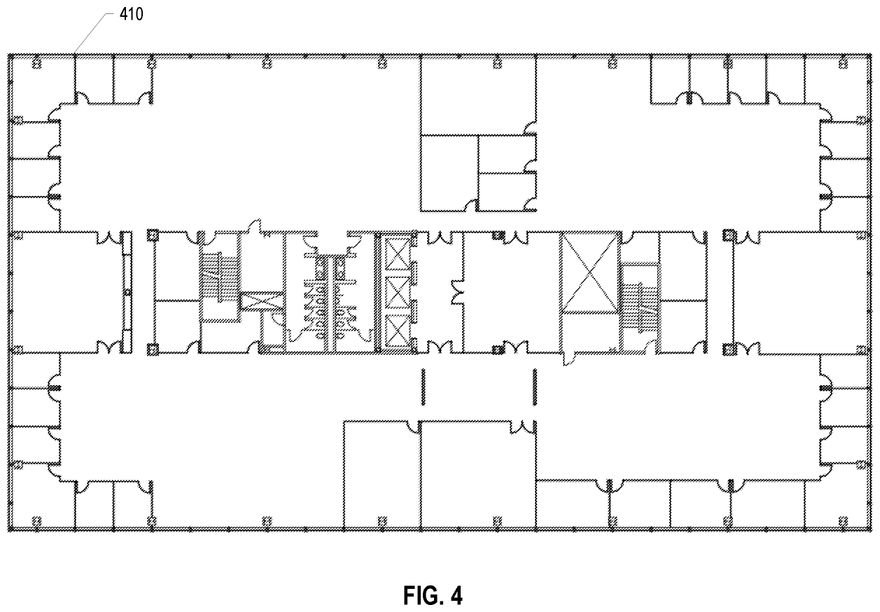

Next, at operation 215, the preprocessor 115 performs preprocessing on the floor plan image to generate a preprocessed floor plan 117. Preprocessing includes preparing the data of the input floor plan 105 to make it suitable for the machine learning model 122. Preprocessing may include setting region(s) of interest, removing noise and unrelated peripheral texts and lines, and/or converting/partitioning the floor plan image according to one or more sections to fit the machine learning model. In an embodiment, the preprocessor 115 performs noise reduction to identify and remove noise (e.g., dirty dots, irrelevant grid lines, company logos, peripheral texts, etc.). For example, the floor plan may be too large for a single machine learning model. In such a case, that floor plan is partitioned into several pieces and each piece is processed by the machine learning model one by one. The results are aggregated to reconstruct a material map that corresponds with the size of the floor plan (as will be described later herein). FIG. 4 shows an exemplary preprocessed floor plan 410 of the floor plan 310. As compared to the floor plan 310, the preprocessed floor plan 410 has noise and some unrelated peripheral texts and lines removed.

Next, at operation 220, the material estimator 120 generates a material map 124 for the preprocessed floor plan 117. The material estimator 120 uses the machine learning model 122, which may be a pretrained U-Net model or its variant, for estimating materials of obstacles such as walls, columns, and/or fixtures, in the preprocessed floor plan. The material map 124 indicates the materials of objects. The indication can be made in different ways. In one way, color may be used to identify different materials. For instance, pink may identify drywall; sky blue may identify glass; brown may identify heavy concrete; dark blue may identify metal; and yellow may identify partition. Of course, these are examples and different colors may identify different materials. In addition to and/or in lieu of colors, different line styles may be used to identify different materials (e.g., solid line, dotted line, dashed line, dot-dash lines, etc.).

In an embodiment, the machine learning model 122 performs pixel-to-pixel estimation. For instance, the machine learning model 122 is a U-Net model that is pretrained as a generator in a cGAN and the discriminator uses a convolutional PatchGAN classifier. The machine learning model 122 has been trained using previous pairs of floor plans and their respective material maps before being used. In an embodiment, the machine learning model 122 is integrated within the material estimator 120. When training the generator, a typical GAN loss function such as root mean square error (RMSE) is not used. Instead, function that considers losses on obstacles only when training the machine learning model such as a focal Tversky loss function is used when training the generator. The focal Tversky loss function suppresses the effect of a blank background in addition to the typical GAN loss.

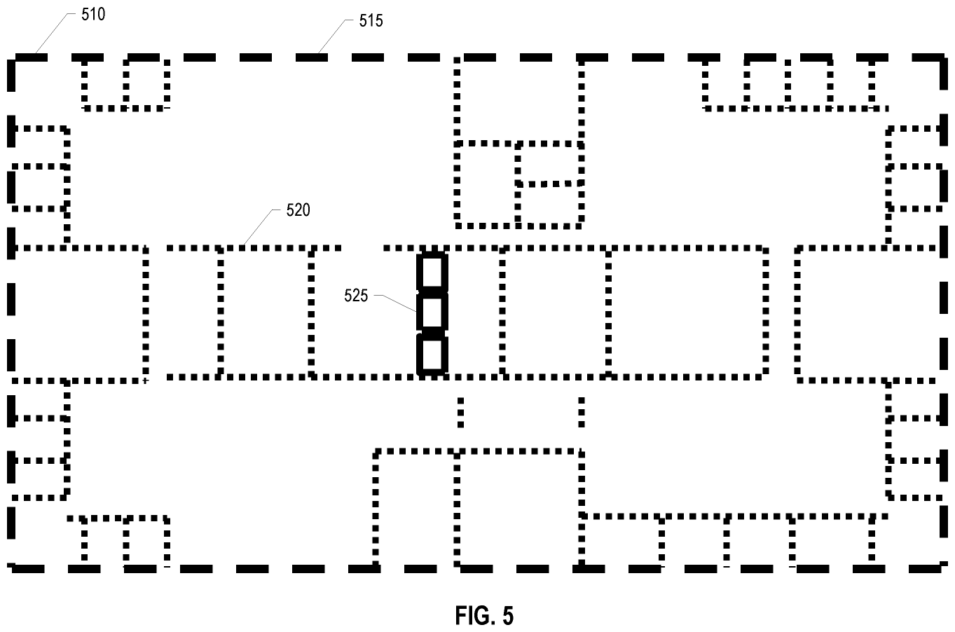

FIG. 5 shows an example material map 510 generated for the preprocessed floor plan 117. The material map 510 visually identifies the different materials. The example in FIG. 5 shows the identification using different line styles. For instance, the dashed lines 515 indicate glass; the square dotted lines 520 indicate drywall; and the solid thick lines 525 indicate concrete. In an embodiment, the machine learning model 122 has learned to not predict material on some items such as text and/or stairs. For instance, the exemplary preprocessed floor plan 410 of FIG. 4 includes stairs, text, and other objects for which the machine learning model 122 has learned to not predict materials and thus are not represented in the material map 510. The examples in FIG. 5 are examples. In an embodiment, the material map uses colors to identify the materials. For instance, pink may identify drywall; sky blue may identify glass; brown may identify heavy concrete; dark blue may identify metal; and yellow may identify partitions. The number and type of identified materials are exemplary in FIG. 5. There may be more or fewer identified materials.

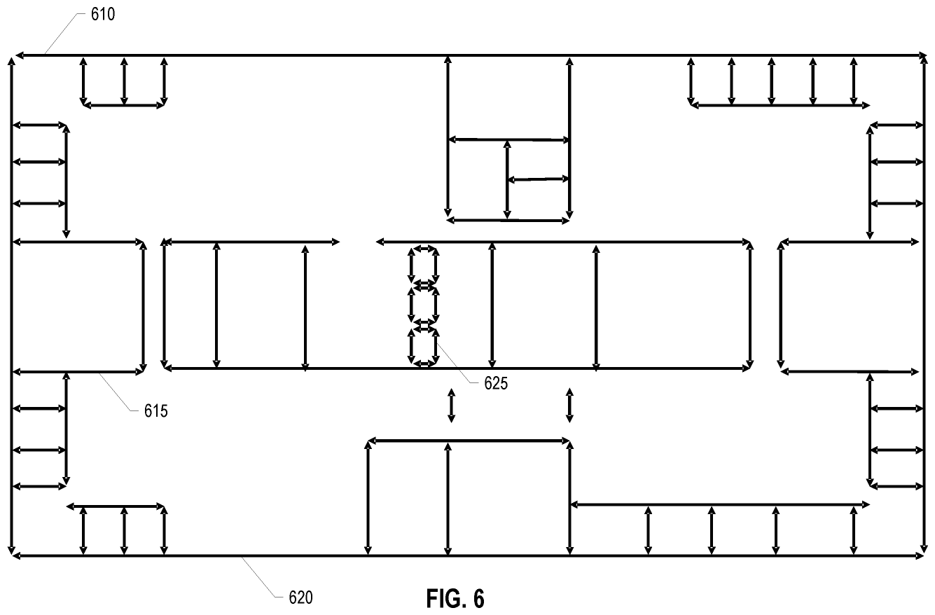

At operation 225, the segmenter 118 generates an obstacle map 119 from the preprocessed floor plan 117 (or from the floor plan 105 in another embodiment). For instance, the segmenter 118 may perform a raster to vector conversion of the raster graphic preprocessed floor plan 117 and segments the line to a set of one or more multiple line segments. FIG. 6 shows an exemplary obstacle map 610. The exemplary obstacle map 610 shows the lines with arrows to illustrate the different line segments. However, in practice, an obstacle map may not include such arrows. As examples, the line segment 615 is an interior obstacle (e.g., an internal wall), the line segment 620 is an obstacle (e.g., an outer wall), and the line segment 625 is an obstacle (e.g., an elevator). In an embodiment, the segmenter 118 does not segment lines on some items such as text and/or stairs. For instance, the exemplary preprocessed floor plan 410 of FIG. 4 includes stairs, text, and other objects that are not segmented by the segmenter 118 and thus are not represented in the obstacle map 610. The operation 225 may be performed in parallel with operation 220 or prior to operation 220.

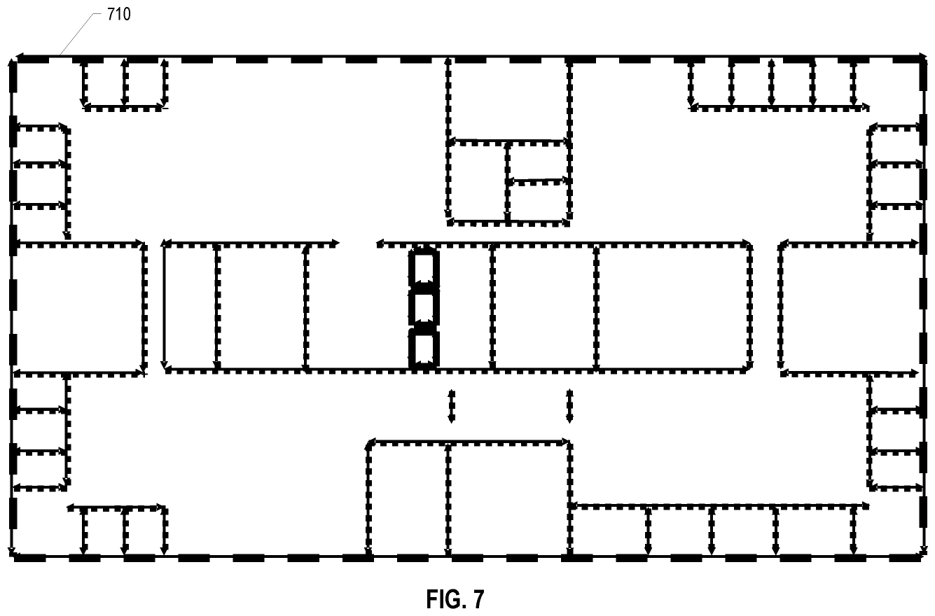

Next, at operation 230, the floor plan augmenter 125 generates an augmented floor plan. Generating an augmented floor plan may include generating a floor plan with obstacle material information from the combination of the material map 124 and the obstacle map 119. The overlap of the material map 124 and the obstacle map 119 is used to associate a material with the obstacle. FIG. 7 shows an exemplary augmented floor plan 710. As an example, the line segments that overlap with the dashed lines 515 (e.g., the outer line segments) are associated with glass; the line segments that overlap with the square dotted lines 520 (e.g., the interior line segments) are associated with drywall; and the line segments that overlap with the solid think lines 525 (e.g., the elevator) are associated with concrete.

Next, at operation 235, the augmented floor plan is provided to the RF design/simulation tool 135. Providing the augmented floor plan may include converting the augmented floor plan to a format that is readable for the RF design/simulation tool 135.

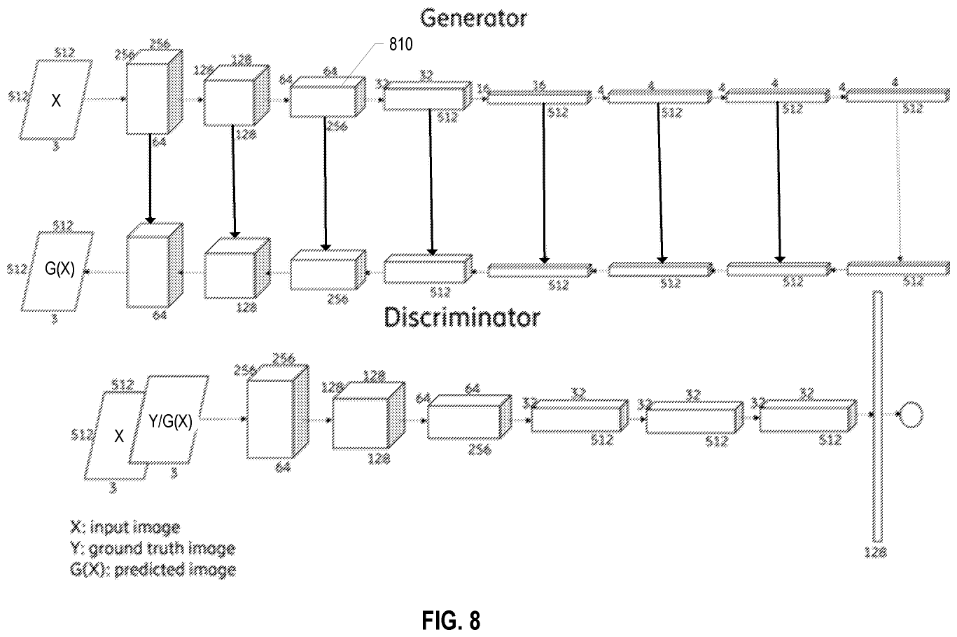

As described herein, a machine learning model is used to estimate obstacle materials from floor plans. FIG. 8 shows an exemplary DNN model for estimating obstacle materials from floor plans. The machine-learning model may be a conditional Generative Adversarial Network (cGAN) discussed herein above. FIG. 8 shows a generator of the neural network and a discriminator of the neural network. The generator may be a modified U-Net and trained in the cGAN framework with its discriminator during training. The U-Net may be modified by including different kernel size (e.g., 4×4 instead of a conventional 3×3), a different activation function (e.g., Leaky ReLu versus a ReLu), and the addition of spectral normalization to stabilize training.

Image X is the input image, which includes a floor plan. For instance, Image X is the preprocessed floor plan 117. Image Y is the ground truth image, which is a desirable output image of the model. For instance, the ground truth image may be the material-augmented floor plan made by human designers. Image G(X) is the predicted image. The numbers accompanying the blocks represent the image/filter dimension and the number of channels of the blocks. For example, at node 810, the numbers 64 and 64 form the dimension of the node (width and height respectively), and the number of channels is 256. Each convolutional layer extracts features from the previous layer and passes it to the next layer. The shallow layers are responsible for extracting low-level features from a given image such as different type of lines. The middle layers are responsible for extracting mid-level features such as shape and texture. The deep layers are responsible for extracting high-level features such as object, composition of different shapes, or even more complicated signals.

A U-Net is a special encoder-decoder network in that it concatenates each layer in the encoder to the symmetric layer in the decoder. The encoder tries to compress different levels of information as tight as possible, and the decoder tries to decode and transform them to another image with the help of cascading with the corresponding encoder layer. This bypass scheme will minimize the sketch structure loss through the entire feature extraction and reconstruction process. For the discriminator, one embodiment selects an encoder only network in the architecture. The encoder here serves the same purpose of extracting low-level to high-level features. But unlike the generator, the goal for the discriminator is to classify between a real image and a fake image from the generator. Therefore, the deep layer features are sufficient to achieve this task. In one embodiment, the PatchGAN architecture is used to output a matrix of probabilities for the final layer in the discriminator to show whether each section of the image can be classified as the real image or not.

In an embodiment, when training the generator, a typical GAN loss function such as root mean square error (RMSE) is not used. Instead, a function that considers losses on obstacles only when training the machine learning model such as a focal Tversky loss function is used when training the generator. The focal Tversky loss function suppresses the effect of a blank background in addition to the typical GAN loss.

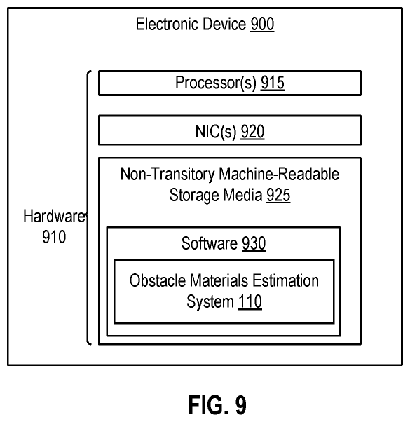

FIG. 9 illustrates an electronic device according to an embodiment. The electronic device 900 may be implemented using custom application-specific integrated circuits (ASICs) as processors and a special-purpose operating system (OS), or common off-the-shelf (COTS) processors and a standard OS. The electronic device 900 includes hardware 910 that includes a set of one or more processors 915 (which are typically COTS processors or processor cores or ASICs), network interface(s) 920, and non-transitory machine-readable storage media 925 having stored therein software 930. During operation, the one or more processors 915 may execute the software 930. The software 930 contains the obstacle materials estimation system 110 that can perform operations in the one or more of exemplary methods described with reference to earlier figures.

An electronic device stores and transmits (internally and/or with other electronic devices over a network) code (which is composed of software instructions and which is sometimes referred to as computer program code or a computer program) and/or data using machine-readable media (also called computer-readable media), such as machine-readable storage media (e.g., magnetic disks, optical disks, solid state drives, read only memory (ROM), flash memory devices, phase change memory) and machine-readable transmission media (also called a carrier) (e.g., electrical, optical, radio, acoustical, or other forms of propagated signals—such as carrier waves, infrared signals). Thus, an electronic device (e.g., a computer) includes hardware and software, such as a set of one or more processors (e.g., of which a processor is a microprocessor, controller, microcontroller, central processing unit, digital signal processor, application specific integrated circuit (ASIC), field programmable gate array (FPGA), other electronic circuitry, or a combination of one or more of the preceding) coupled to one or more machine-readable storage media to store code for execution on the set of processors and/or to store data. For instance, an electronic device may include non-volatile memory containing the code since the non-volatile memory can persist code/data even when the electronic device is turned off (when power is removed). When the electronic device is turned on, that part of the code that is to be executed by the processor(s) of the electronic device is typically copied from the slower non-volatile memory into volatile memory (e.g., dynamic random-access memory (DRAM), static random-access memory (SRAM)) of the electronic device. Typical electronic devices also include a set of one or more physical network interface(s) (NI(s)) to establish network connections (to transmit and/or receive code and/or data using propagating signals) with other electronic devices. For example, the set of physical NIs (or the set of physical NI(s) in combination with the set of processors executing code) may perform any formatting, coding, or translating to allow the electronic device to send and receive data whether over a wired and/or a wireless connection. In some embodiments, a physical NI may comprise radio circuitry capable of (1) receiving data from other electronic devices over a wireless connection and/or (2) sending data out to other devices through a wireless connection. This radio circuitry may include transmitter(s), receiver(s), and/or transceiver(s) suitable for radiofrequency communication. The radio circuitry may convert digital data into a radio signal having the proper parameters (e.g., frequency, timing, channel, bandwidth, and so forth). The radio signal may then be transmitted through antennas to the appropriate recipient(s). In some embodiments, the set of physical NI(s) may comprise network interface controller(s) (NICs), also known as a network interface card, network adapter, or local area network (LAN) adapter. The NIC(s) may facilitate in connecting the electronic device to other electronic devices allowing them to communicate with wire through plugging in a cable to a physical port connected to an NIC. One or more parts of an embodiment may be implemented using different combinations of software, firmware, and/or hardware.

Although the computing devices described herein (e.g., electronic device) may include the illustrated combination of hardware components, other embodiments may comprise computing devices with different combinations of components. It is to be understood that these computing devices may comprise any suitable combination of hardware and/or software needed to perform the tasks, features, functions and methods disclosed herein. Determining, calculating, obtaining or similar operations described herein may be performed by processing circuitry, which may process information by, for example, converting the obtained information into other information, comparing the obtained information or converted information to information stored in the network node, and/or performing one or more operations based on the obtained information or converted information, and as a result of said processing making a determination. Moreover, while components are depicted as single boxes located within a larger box, or nested within multiple boxes, in practice, computing devices may comprise multiple different physical components that make up a single illustrated component, and functionality may be partitioned between separate components. For example, a communication interface may be configured to include any of the components described herein, and/or the functionality of the components may be partitioned between the processing circuitry and the communication interface. In another example, non-computationally intensive functions of any of such components may be implemented in software or firmware and computationally intensive functions may be implemented in hardware.

In certain embodiments, some or all the functionality described herein may be provided by processing circuitry executing instructions stored on in memory, which in certain embodiments may be a computer program product in the form of a non-transitory computer-readable storage medium. In alternative embodiments, some or all the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the computing device but are enjoyed by the computing device as a whole, and/or by end users and a wireless network generally.

### EMBODIMENTS

### Group A Embodiments

1. A method for estimating materials of obstacles from a floor plan, the method comprising:
   loading and preprocessing the floor plan;
   generating a material map for the preprocessed floor plan using a machine learning model for estimating materials of obstacles of the floor plan;
   generating an obstacle map from the preprocessed floor plan that includes segmented obstacles as line segments; and
   generating, based on a combination of the generated material map and the generated obstacle map, an augmented floor plan that identifies the estimated material of the segmented obstacles.
2. The method of embodiment 1, further comprising:
   providing the generated augmented floor plan to a radio frequency (RF) design/simulation tool.
3. The method of embodiment 2, wherein providing the generated augmented floor plan to the RF design/simulation tool includes converting the generated augmented floor plan to a format readable by the RF design/simulation tool.
4. The method of any of the previous embodiments, wherein preprocessing the floor plan includes setting one or more regions of interest.
5. The method of any of the previous embodiments, wherein preprocessing the floor plan includes removing noise and unrelated peripheral texts and lines.
6. The method of any of the previous embodiments, wherein the machine learning model is a U-Net model that is pretrained as a generator in a conditional generative adversarial network (cGAN).
7. The method of embodiment 6, wherein the cGAN uses a function that considers losses on obstacles only when training the machine learning model such as a focal Tversky loss function.
8. The method of embodiments 6 or 7, wherein a discriminator of the cGAN uses a convolutional PatchGAN classifier.
9. The method of any of the previous embodiments, wherein the obstacles of the floor plan include one or more walls, one or more columns, and/or one or more fixtures.
10. The method of any of the previous embodiments, wherein generating the obstacle map includes vectorizing the preprocessed floor plan to the line segments.
11. The method of any of the previous embodiments, wherein the floor plan is a raster graphics image, and wherein the generated obstacle map is a vector graphic.
12. The method of any of the previous embodiments, wherein the generated material map and the generated obstacle map are spatially aligned.

### Group B Embodiments

13. An electric device for estimating materials of obstacles from a floor plan, comprising:
   processing circuitry configured to perform any of the steps of any of the Group A embodiments; and
   power supply circuitry configured to supply power to the processing circuitry.
14. A non-transitory computer-readable storage medium that provides instructions that, if executed by a processor, will cause said processor to perform any of the steps of any of the Group A embodiments.
15. An electronic device for estimating materials of obstacles from a floor plan, the electronic device comprising:
   a processor; and
   a non-transitory computer-readable storage medium that provides instructions that, if executed by the processor, cause the electronic device to perform any of the steps of any of the Group A embodiments.
16. A machine-readable medium comprising computer program code which when executed by an electronic device carries out any of the steps of any of the Group A embodiments.
17. A system for estimating materials of obstacles from a floor plan, comprising:
   a non-transitory computer-readable storage medium that provides instructions that, if executed by a processor, will cause said processor to perform any of the steps of any of the Group A embodiments.

### References

Ahmat et al., “System and Methods for Designing a Distributed MIMO Network”, WO 2019/220243, filed 24 Apr. 2019 and published 21 Nov. 2019.

Elahi et al., “Performance Simulation of a Distributed MIMI Antenna System”, WO 2019/22044, filed 24 Apr. 2019 and published 21 Nov. 2019.

Park et al., “Method and System for Estimating Indoor Radio Transmitter Count”, WO 2021/161273, filed 12 Feb. 2021 and published 19 Aug. 2021

Park et al., “Method, Electronic Device and Non-Transitory Computer-Readable Storage Medium For Determining Indoor Radio Transmitter Distribution”, WO 2021/176262, filed 11 May 2020 and published 10 Sep. 2021.

Ronneberger, O., Fischer, P., & Brox, T. (2015). U-Net: Convolutional Networks for Biomedical Image Segmentation. MICCAI.

Isola, P., Zhu, J., Zhou, T., & Efros, A.A. (2017). Image-to-Image Translation with Conditional Adversarial Networks. 2017 IEEE Conference on Computer Vision and Pattern Recognition (CVPR), 5967-5976.

Liu, C., Chang, H., & Park, T. (2020). DA-cGAN: A Framework for Indoor Radio Design Using a Dimension-Aware Conditional Generative Adversarial Network. 2020 IEEE/CVF Conference on Computer Vision and Pattern Recognition Workshops (CVPRW), 2089-2098.

1. A method for estimating materials of obstacles from a floor plan, the method comprising:
loading and preprocessing the floor plan;
generating a material map for the preprocessed floor plan using a machine learning model for estimating materials of obstacles of the floor plan;
generating an obstacle map from the preprocessed floor plan that includes segmented obstacles as line segments; and
generating, based on a combination of the generated material map and the generated obstacle map, an augmented floor plan that identifies the estimated material of the segmented obstacles.

2. The method of claim 1, further comprising:
converting the generated augmented floor plan to a format readable by a radio frequency (RF) design/simulation tool; and
providing the generated augmented floor plan to the RF design/simulation tool.

3. (canceled)

4. The method of claim 1, wherein preprocessing the floor plan includes setting one or more regions of interest.

5. The method of claim 1, wherein preprocessing the floor plan includes removing noise and unrelated peripheral texts and lines.

6. The method of claim 1, wherein the machine learning model is a U-Net model that is pretrained as a generator in a conditional generative adversarial network (cGAN), wherein the cGAN uses a function that considers losses on obstacles only when training the machine learning model such as a focal Tversky loss function, and wherein a discriminator of the cGAN uses a convolutional PatchGAN classifier.

7. (canceled)

8. (canceled)

9. The method of claim 1, wherein the obstacles of the floor plan include one or more walls, one or more columns, and/or one or more fixtures.

10. The method of claim 1, wherein the floor plan is a raster graphics image, and wherein generating the obstacle map includes vectorizing the preprocessed floor plan to the line segments.

11. (canceled)

12. (canceled)

13. (canceled)

14. (canceled)

15. (canceled)

16. (canceled)

17. (canceled)

18. A non-transitory computer-readable storage medium that provides instructions that, if executed by a processor, will cause said processor to perform operations for estimating materials of obstacles from a floor plan, the operations comprising:
loading and preprocessing the floor plan;
generating a material map for the preprocessed floor plan using a machine learning model for estimating materials of obstacles of the floor plan;
generating an obstacle map-from the preprocessed floor plan that includes segmented obstacles as line segments; and
generating, based on a combination of the generated material map and the generated obstacle map, an augmented floor plan that identifies the estimated material of the segmented obstacles.

19. The non-transitory computer-readable storage medium of claim 18, wherein the operations further comprise:
converting the generated augmented floor plan to a format readable by a radio frequency (RF) design/simulation tool; and
providing the generated augmented floor plan to the RF design/simulation tool.

20. The non-transitory computer-readable storage medium of claim 18, wherein preprocessing the floor plan includes setting one or more regions of interest.

21. The non-transitory computer-readable storage medium of claim 18, wherein preprocessing the floor plan includes removing noise and unrelated peripheral texts and lines.

22. The non-transitory computer-readable storage medium of claim 18, wherein the machine learning model is a U-Net model that is pretrained as a generator in a conditional generative adversarial network (cGAN), wherein the cGAN uses a function that considers losses on obstacles only when training the machine learning model such as a focal Tversky loss function, and wherein a discriminator of the cGAN uses a convolutional PatchGAN classifier.

23. The non-transitory computer-readable storage medium of claim 18, wherein the obstacles of the floor plan include one or more walls, one or more columns, and/or one or more fixtures.

24. The non-transitory computer-readable storage medium of claim 18, wherein the floor plan is a raster graphics image, and wherein generating the obstacle map includes vectorizing the preprocessed floor plan to the line segments.

25. An electronic device for estimating materials of obstacles from a floor plan, the electronic device comprising:
a processor; and
a non-transitory computer-readable storage medium that provides instructions that, if executed by the processor, cause the electronic device to perform operations including:
loading and preprocessing the floor plan,
generating a material map for the preprocessed floor plan using a machine learning model-for estimating materials of obstacles of the floor plan,
generating an obstacle map-from the preprocessed floor plan that includes segmented obstacles as line segments, and
generating, based on a combination of the generated material map and the generated obstacle map, an augmented floor plan that identifies the estimated material of the segmented obstacles.

26. The electronic device of claim 25, wherein the operations further comprise:
converting the generated augmented floor plan to a format readable by a radio frequency (RF) design/simulation tool; and
providing the generated augmented floor plan to the RF design/simulation tool.

27. The electronic device of claim 25, wherein preprocessing the floor plan includes setting one or more regions of interest.

28. The electronic device of claim 25, wherein preprocessing the floor plan includes removing noise and unrelated peripheral texts and lines.

29. The electronic device of claim 25, wherein the machine learning model is a U-Net model that is pretrained as a generator in a conditional generative adversarial network (cGAN), wherein the cGAN uses a function that considers losses on obstacles only when training the machine learning model such as a focal Tversky loss function, and wherein a discriminator of the cGAN uses a convolutional PatchGAN classifier.

30. The electronic device of claim 25, wherein the obstacles of the floor plan include one or more walls, one or more columns, and/or one or more fixtures.
